(19) United States
(12) Patent Application Publication
(10) Pub. No.: US 2005/0237723 A1
(43) Pub. Date: Oct. 27, 2005

(54) Computer casing

(76) Inventor: Yin-Hung Chen, Taipei (TW)

Correspondence Address: Yi-Wen Tseng, 4331 Stevens Battle Lane, Fairfax, VA, 22033, US

(21) Appl. No.: 10/828,271

(22) Filed: Apr. 21, 2004

(51) Int. Cl. H05K 5/00

(52) U.S. Cl. 361/752

(57) ABSTRACT

A computer casing having a front board, a back board, a bottom board, a top board, a left side board and a right side board, includes an internal space and a supporting structure. The internal space is used for mounting a mother board, a CPU, a heat dissipating device and plural electrical elements therein. The supporting structure is mounted on the bottom board corresponding to a position of the CPU and the heat dissipating device. In which the supporting structure is a hollow space having a stronger structural intensity than other part of the bottom board. The hollow space has four pillars protrudently mounted at four corners of the hollow space respectively for screwing and fixing the heat dissipating device thereon. Accordingly, the hollow space is employed for strengthening the structural intensity so that the bottom board can hold the CPU and heat dissipating stably without being caved in.

### BACKGROUND OF THE INVENTION

The present invention is related to a computer casing, and more particularly, to a computer casing having a supporting structure formed on the bottom board thereof. With the supporting structure, the CPU and the heat dissipating device of the computer can be supported stably.

It has been general consuming needs that the electronic equipments are small, thin, and light. Accordingly, all electronic equipments are designed as light as they can be in order to satisfy the needs. For a computer host machine, the best way to reduce its weight is to lighten the weight of the casing or reduce the number of the elements. When trying to design a lighter casing, the feature and property of material are considered, i.e., the casing made of aluminum-magnesium alloy is lighter. On the other hand, the thickness of the side boards of computer casing can be designed thinner as well in order to lighten the total weight of computer host machine.

However, when the thicknesses of all the side boards of computer casing are designed thinner, the structural strength of the casing would be affected. Especially the bottom board might have a structural deformation after the heat dissipating device, the heaviest element inside the computer host machine, is mounted on the mother board. When the bottom board of the casing can not provide enough support because of the thinner thickness, the position on the bottom board where the heat dissipating device is located will be depressed.

Hence, how to prevent from the problem of shape deformation of the bottom board has become a serious problem in the industry. In order to overcome the drawbacks in the prior art, a computer casing with a supporting structure, which provides a stronger structural strength, is disclosed.

### SUMMARY OF THE INVENTION

The present invention is to provide a computer casing which has a supporting structure mounted on the bottom board of the computer casing. Through the supporting structure, the structural strength of the position on the bottom board corresponding to the location of the heat dissipating device is highly improved.

According to one aspect of the present invention, a computer casing having a front board, a back board, a bottom board, a top board, a left side board and a right side board, provides an internal space and a supporting structure. The internal space is used for installing a mother board, a CPU, a heat dissipating device and plural electrical elements therein. The heat dissipating device is mounted on the CPU. The supporting structure is formed on the bottom board corresponding to the location of the CPU and the heat dissipating device. The supporting structure includes a dent portion providing a structural strength stronger than any other part of the bottom board. Besides there are four pillars protruded at four corners of the dent portion respectively so that the heat dissipating device is fixed to the mother board by screwing a plurality of fixing elements through the mother board in the four pillars, respectively. Accordingly, the dent portion provides a stronger structure around the location where the heat dissipating device is mounted so that the bottom board can hold the CPU and heat dissipating stably without being depressed.

The foregoing and other features and advantages of the present invention will be more clearly understood through the following descriptions with reference to the drawings, wherein:

### BRIEF DESCRIPTION OF THE DRAWINGS

FIG. 1 is a schematic diagram showing the outside appearance of the computer casing according to a preferred embodiment of the present invention;

FIG. 2 is a sectional view showing partial computer casing according to a preferred embodiment of the present invention;

FIG. 3 is a schematic diagram showing the outside appearance of the computer casing which has the mother board and heat dissipating device mounted therein according to a preferred embodiment of the present invention; and

FIG. 4 is a sectional view showing partial portion of FIG. 3 according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

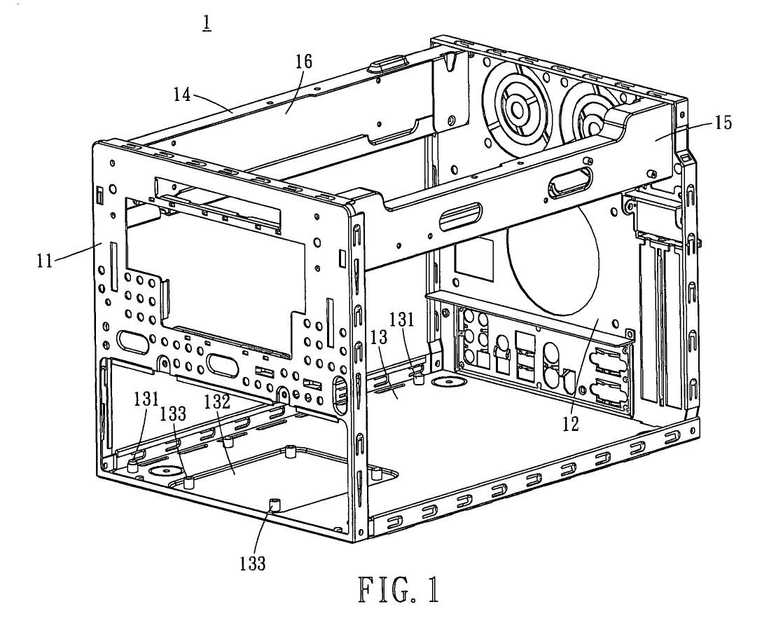

A computer casing having a supporting structure is provided in the present invention. Please refer to FIG. 1. The computer casing 1 is generally a rectangular solid. The computer casing 1 is defined as having a front board 11, a back board 12, a bottom board 13, a top board 14, a left side board 15 and a right side board 16. The distance between the front board 11 and the back board 12 is lengthier than that between the left side board 15 and the right side board 16. There are devices like disk cartridge and CD-ROM drive mounted on the front board 11 of the computer casing 1. And there are elements like power socket and connection ports for different interfaces mounted on the back board 12.

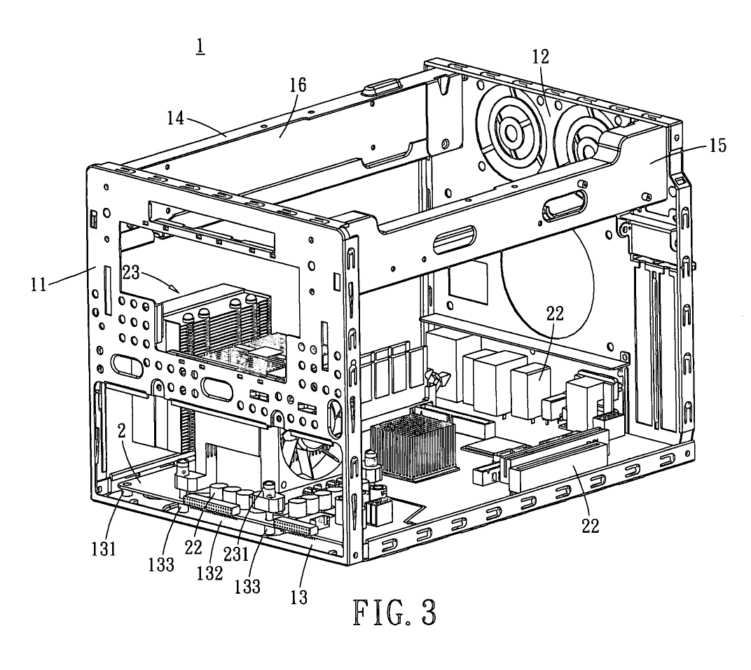

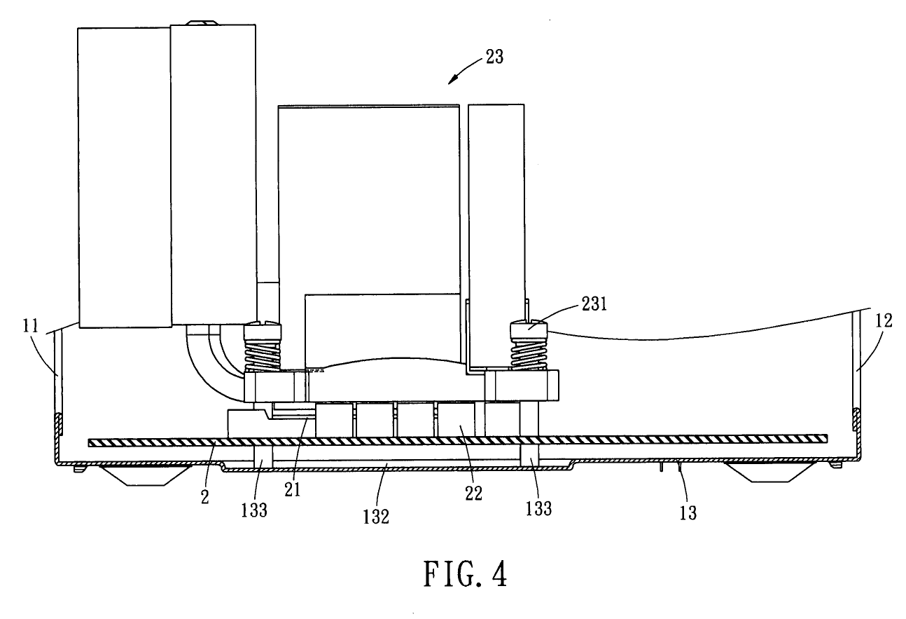

The bottom board 13 has plural posts 131 protrudently mounted on the peripheral sides for fixedly screwing the mother board 2 thereon, as shown in FIG. 3. The CPU 21 and the electrical elements or devices 22 are mounted on the mother board 2, as shown in FIG. 4. Also, the heat dissipating device 23 is mounted on the CPU 21.

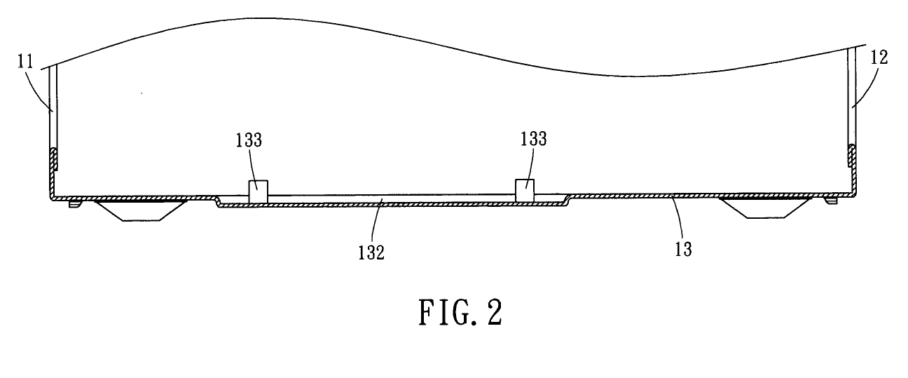

Please refer to FIGS. 1 and 2. According to a preferred embodiment of the present invention, the supporting structure mounted on the bottom board 13 corresponding to a position of the CPU 21 and the heat dissipating device 23. The supporting structure is a hollow space 132 which has a stronger structural intensity than other part of the bottom board 13. The hollow space 132 has four pillars 133 protrudently mounted at four corners of the hollow space 132 respectively so that the heat dissipating device 23 is screwed on the four pillars 133.

Please refer to FIGS. 3 and 4. When mounting the mother board 2 and the heat dissipating device 23 inside the computer casing 1, through the screw elements, the mother board 2 is screwed on the posts 131 mounted on the peripheral sides of the bottom board 13 so as to fix the mother board 2 inside the computer casing 1. The heat dissipating device 23 is screwed passing through the mother board 2 by the screw elements 231 and thereby fixed on the pillars 133 mounted in the hollow space 132. Accordingly, the heat dissipating device 23 is mounted above the CPU 21, while the CPU 21 and the heat dissipating device 23 are positioned above the hollow space 132.

Based on the preferred embodiment of the present invention, since the hollow space 132 is only a small part on the bottom board 13, the structural intensity around this area is the most powerful. Therefore, when the CPU 21 and the heat dissipating device 23 are positioned above the hollow space 132, the hollow space 132 will be able to endure the weight of the heat dissipating device 23. The bottom board would not have a shape deformation around this area so that the bottom board 13 of the computer casing is able to support the CPU 21 and the heat dissipating device 23.

According to the above, the drawbacks in the conventional computer casing are not existed in the present invention. With the particular design of the supporting structure, the computer casing is able to stably support the heavy-weight the CPU 21 and the heat dissipating device 23 without having a shape deformation. Hence, the present invention not only has a novelty and a progressive nature, but also has an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A computer casing having a front board, a back board, a bottom board, a top board, a left side board and a right side board, comprising:
an internal space formed by the front board, the back board, the bottom board, the top board, the left side board and the right side board, for mounting a mother board, a CPU, a heat dissipating device and plural electrical elements therein, wherein the heat dissipating device is mounted on the CPU; and
a supporting structure formed on the bottom board corresponding to a location of the CPU and the heat dissipating device, wherein the supporting structure includes a dent portion to provide a structural strength stronger than any other part of the bottom board.

2. The computer casing according to claim 1, wherein the supporting structure further includes a plurality of pillars protruded at four corners thereof, and a plurality of fixing elements are used to fix the heat dissipating device to the mother board by passing through the mother board to screw in corresponding pillars.
